(19) United States
(12) Patent Application Publication
(10) Pub. No.: US 2002/0016698 A1
(43) Pub. Date: Feb. 7, 2002

(54) Device and method for audio frequency range expansion

(76) Inventor: Toshimichi Tokuda, Maebaru-shi (JP)

Correspondence Address: MCDERMOTT, WILL & EMERY, 600 13th Street, N.W., Washington, DC, 20005-3096, US

(21) Appl. No.: 09/888,612

(22) Filed: Jun. 26, 2001

(30) Foreign Application Priority Data
Jun. 26, 2000 (JP) 2000-190922

(51) Int. Cl. H03F 1/26; H04B 15/00; G06F 15/00

(52) U.S. Cl. 702/190

(57) ABSTRACT

The disclosed device for audio frequency range expansion compensates the vocal range by a small quantity of operation, and improves the tone quality and verbal perception. Analog-to-digital converting means converts an input analog narrow frequency band audio signal into a digital signal. Voiced/voiceless judging means distinguishes the voiceless sound section and voiced sound section of audio signal. Aliasing signal generating means disposes sampled signals on every relevant order of sample point of digital signals issued from the analog-to-digital converting means, and replaces the value of the every relevant order of sample point spuriously with zero value. A filter changes over the filter characteristic based on the judged result of the voiced/voiceless judging means. Digital-to-analog converting means converts an output digital signal from the filter into an analog signal.

### FIELD OF THE INVENTION

The present invention relates to device and method for audio frequency range expansion for generating a wide frequency band audio signal spuriously from a narrow frequency band audio signal.

### BACKGROUND OF THE INVENTION

The barrier-free society is highly needed recently. From such viewpoint, in audio communication appliances, for the elderly people or others having difficulty in hearing, there is a increasing demand for development of technology for generating a more audible audio signal by expanding apparently the band of audio signal. Usually, the audio signal through telephone line is one of the standards in audio communication mainly by verbal expression. The audio signal by telephone is limited in the frequency band width, and its tone quality is not generally excellent as compared with the original voice. For example, even in the wire telephone line of relatively favorable tone quality, the actual audio frequency band width is limited to about 300 to 3500 Hz, witch is about half of human voice frequency range. The human vocal frequency range is generally composed of fundamental frequencies of 80 Hz to 800 Hz and higher harmonics of several degrees thereof in the Japanese male voice, and is 150 Hz to 1600 Hz and higher harmonics of several degrees thereof in the Japanese female voice. Including the higher harmonics of several degrees and further voiceless sound, the vocal range is as wide as 80 Hz to 16 kHz. It is important, in comprehension of spoken words and pleasant tone quality of spoken words particularly, for the human voice to have the frequency components including harmonics of several degrees higher than 3500 Hz and to have the frequency components including the fundamental frequencies of spoken words lower than 300 Hz. The telephone line and other transmission line of narrow frequency band dissipate not only the majority of these important high and low frequency components of voiced sound but also high frequency components of voiceless sound, so that they deteriorate the tone quality of verbal audio signal in hearing. Narrowed frequency band of audio signal impedes ease of hearing and the comprehension degree. As a result, narrowed frequency band of audio signal is reported to be a serious problem for the elderly people or others having difficulty in hearing (Proceeding of the 1996 Autumn Meeting of Acoustic Society of Japan, Vol. 1, 2-6-5, 1996).

To solve such problems, various methods and devices for expanding the frequency band of audio signals have been attempted so far. However, although they require a tremendous quantity of operation steps and memory capacity, but the processed signals are not always satisfactory in the tone quality. For example, one of a typical conventional method is the codebook mapping method, which matches an input voice of telephone frequency band with recorded voice of wide frequency band by using a codebook, so as to generate high quality voice. But, this method not only requires a lot of matching operation steps and a lot of memories for codebook and for recorded high quality voices, but also tends to be unstable in the matching precision depending on the line status.

Another expansion method of audio frequency is on the synthesis by analysis method, which also requires a detailed and tremendous operation steps for analysis and then for synthesis. The obtained result is not satisfactory as compared with the required cost for installation.

An exceptional method has been proposed to compensate virtually the high frequency signal by using aliasing signal and fixed filter in small operation steps. This method, however, cannot expand sufficiently the high frequency range of voiceless sound, and so it does not improve the clarity and perception of sound, and then results in a dull sound.

### SUMMARY OF THE INVENTION

The invention presents devices and methods for solving the problems of conventional method. It is, therefore, an object of the invention practically to improve the tone quality and the perception rate of words using high and low frequency compensation for audible audio signal limited in the frequency band, and using a relatively small operation steps. To achieve the object, the device for audio frequency range expansion of the invention comprises:

a) analog-to-digital converting means for sampling input analog narrow frequency band audio signal at a sampling frequency of four times or more and even number multiple of upper limit frequency, and converting into digital signal,

b) voiced/voiceless judging means for analyzing the digital signal issued from the analog-to-digital converting means, and distinguishing a voiceless sound section not including vowel in the audio signal from a voiced sound section including a vowel,

c) aliasing signal generating means for disposing sampled signal on every relevant order of sample point of digital signals issued from the analog-to-digital converting means, replacing the value of the every relevant order of sample point spuriously with zero value, and generating a digital signal spuriously having frequency components of twice as high as the input frequency components of narrow frequency band audio signal and having a frequency spectrum folded the spectrum of the input signal symmetrically at the frequency axis which is the upper limit frequency of input audio signal,

d) filter for limiting the band of the output signal of the aliasing signal generating means by changing over the low pass filter characteristic to a low cut-off frequency state for the voiced sound section and a high cut-off frequency state for the voiceless sound section, based on the judged result by the voiced/voiceless judging means, and

e) signal converting means for converting a digital signal issued from the filter into an analog signal, and issuing an audio signal of wide frequency band.

Thus, the invention is capable of expanding the frequency band of output audio signal while maintaining the feature of the sound expressed in the original audio signal frequency band width. Moreover, the invention is capable of compensating the audio frequency range practically in a relatively small operation steps, and is capable of improving the sound quality and the listening comprehension of words at the same time. The invention can expand the present narrow frequency band audio signal of telephone voice or AM radio broadcast class substantially into the wide frequency band audio signal of FM radio class. The present invention, moreover, can reinforce the audio signal not only with high frequency band but also with low frequency band spuriously, so that it generates an audio signal of more natural, better quality and better listening perception.

Further, the present invention is capable of adjusting individually each signal level of the high and low frequency range to the original audio signal, so that it realizes high tone quality voice signal.

### BRIEF DESCRIPTION OF THE DRAWINGS

FIG. 1 is a block diagram of a device for audio frequency range expansion according to an embodiment of the invention.

FIG. 2 is a hardware configuration diagram of the device for audio frequency range expansion in the embodiment of the invention.

FIG. 3 is a flowchart for audio frequency range expansion process in the embodiment of the invention.

FIG. 4a is a conceptual diagram showing an example of sampling row of audio signals.

FIG. 4b is a conceptual diagram showing a state of replacing sampled value with a zero value pulse in every other sample of audio signal.

FIG. 5 is a block diagram of a device for audio frequency range expansion according to another embodiment of the invention.

FIG. 6 is a flowchart for audio frequency range expansion process in another embodiment of the invention.

FIG. 7a is a conceptual diagram showing an example of sampling row of audio signals.

FIG. 7b is a conceptual diagram showing a state of inverting the polarity of sampled pulses in every other sample.

FIG. 8 is a flowchart for audio frequency range expansion process according to the other embodiment of the invention.

### DESCRIPTION OF THE PREFERRED EMBODIMENTS

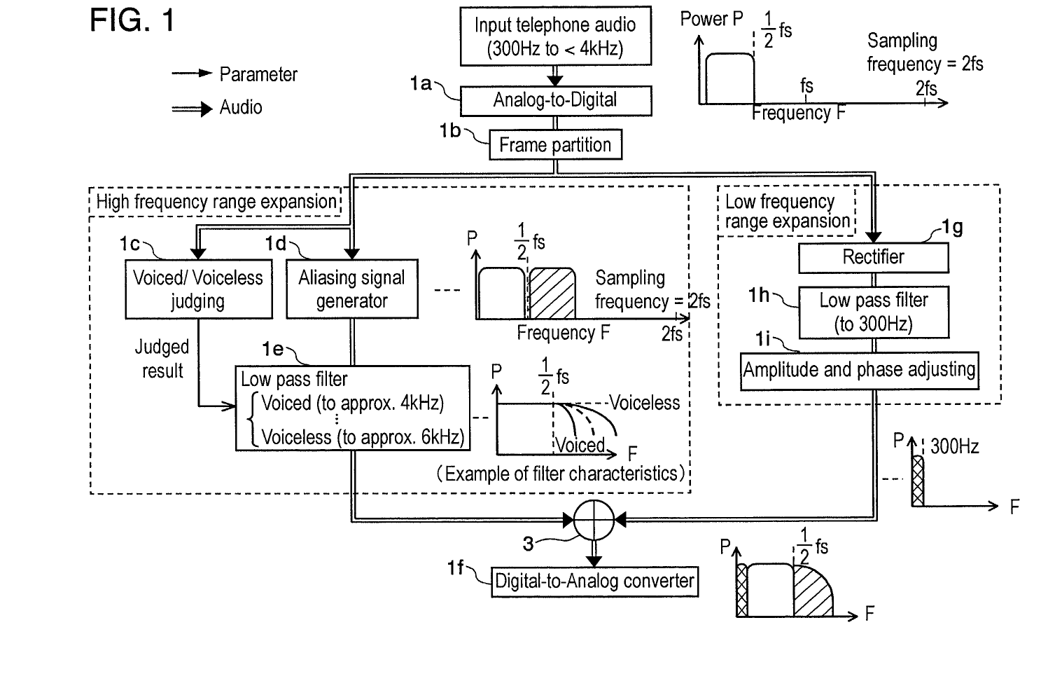

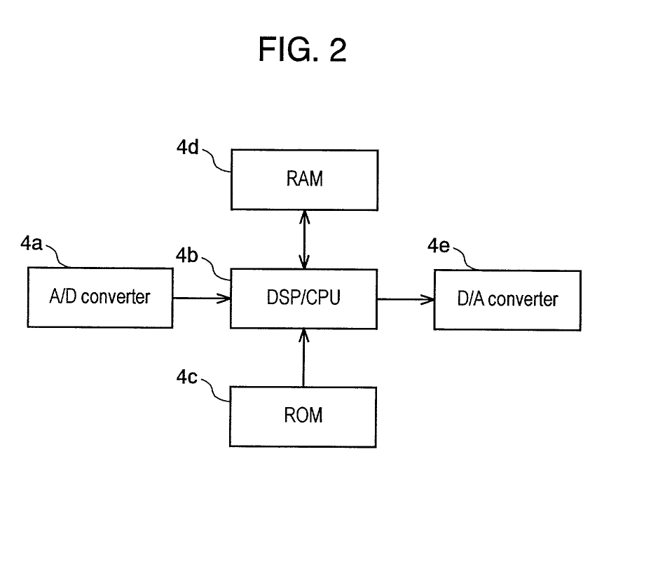

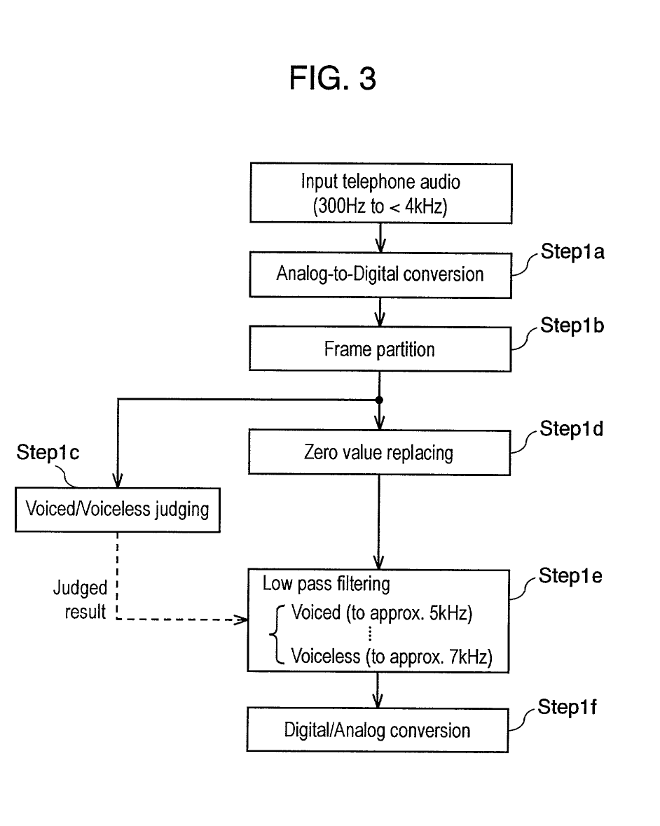

An embodiment of the invention is described below while referring to FIG. 1, FIG. 2, and FIG. 3.

FIG. 1 is a block diagram of a device for audio frequency range expansion according to an embodiment of the invention. FIG. 2 is a hardware configuration diagram of the device for audio frequency range expansion in the embodiment of the invention. FIG. 3 is a flowchart for audio frequency range expansion process in the embodiment of the invention.

In FIG. 1, an analog-to-digital converter 1a samples, for example, input analog narrow frequency band audio signal transmitted through a telephone line at a sampling frequency 2fs of four times of upper limit frequency fs/2, and converts into digital signal having twice samples as much as in the usual case of sampling frequency fs, as shown in FIG. 4a. In this embodiment, every other sample is regarded as necessary sample, but the rest of the sample is regarded as spurious sample which is located alternately in every other sample point with the necessary sample.

Frame partition means 1b divides the narrow frequency band audio signal into time frames of a specific time length on the time series. Actually, one time frame corresponds to the duration of tens to hundreds of milliseconds.

Voiced/voiceless judging means 1c analyzes the digital signal issued from the analog-to-digital converter 1a through the frame partition means 1b, and distinguishes a voiceless sound section likely not including vowel in the audio signal from a voiced sound section likely including a vowel. That is, it analyzes the feature of the narrow frequency band audio signal in each time frame divided in every tens to hundreds of milliseconds per frame. For example, by using the zero-cross number of narrow frequency band audio signal included in one time frame, the time frame is distinguished to be a voiced sound section or a voiceless sound section. In the voiced sound section, the zero-cross is likely to occur periodically. On the other hand, in the voiceless sound section, the zero-cross does not have a clear period. By making use of this difference, the voiced sound section and voiceless sound section can be distinguished. Further, in the voiced sound section, the period of zero-cross is generally long, or, the zero-cross number is small. On the other hand, in the voiceless sound section, the period of zero-cross is short, or, the zero-cross number is large. Hence, the voiced sound section and voiceless sound section can be also distinguished by making use of these characteristics. By setting the zero-cross at a specific number as the threshold of judgement, the voiced sound section and voiceless sound section can be also distinguished based on the threshold value. Incidentally, when the zero-cross number is large, the sound seems more likely to be voiceless.

Aliasing signal generating means 1d replaces the amplitude value of the spurious sample located in the every other sample point with zero value, so that it generates a reinforcing digital signal of which sampling frequency is as it were fs which is twice of upper limit frequency fs/2 of input audio signal, as shown in FIG. 4b. The reinforcing digital signal has a frequency spectrum folded the spectrum of the input signal symmetrically at the frequency axis of fs/2 towards high frequency side up to fs Hz. A low pass filter 1e limits the band of the output signal of the aliasing signal generating means 1d by changing over the low pass filter characteristic to a low cut-off frequency state for the voiced sound section and a high cut-off frequency state for the voiceless sound section based on the judging result in the voiced/voiceless judging means 1c.

A digital-to-analog converter 1f converts a digital signal issued from the low pass filter 1e into an analog signal, and issues an audio signal expanded in the signal component into wide frequency band.

A section of low frequency range expansion comprising a rectifier 1g, a low pass filter 1h, and an amplitude and phase adjuster 1i. The rectifier 1g rectifies the digital signal issued from the analog-to-digital converter 1a. More specifically, the rectifier 1g rectifies the narrow frequency band audio signal partitioned in time frame at a specific time interval in the frame partition means 1b into digital signal. The rectifier 1g is a digital half wave rectifier and it replace the sample value having negative polarity to zero and issues directly the rest of sample values having positive polarity as it is. The low pass filter 1h extracts the sufficient fundamental frequency components of the original audio signal from the signal components obtained by rectifying, that is, low frequency components corresponding to the tone pitch of input audio signal, at a cut-off frequency of 300 Hz. The amplitude and phase adjuster 1i adjusts the phase and amplitude of the low frequency component extracted by the low pass filter. An adder 3 adds the low frequency component from the amplitude and phase adjuster 1i in the section of low frequency expansion to the output signal from the low pass filter 1e in the section of high frequency expansion.

FIG. 2 shows the device for audio frequency range expansion in FIG. 1 realized by using a digital signal processor (DSP) and a central processing unit (CPI). In FIG. 2, an AID converter 4a and a D/A converter 4e correspond to the analog-to-digital converter 1a and the digital-to-analog converter 1f in FIG. 1. Further, a DSP/CPU 4b in FIG. 2 processes the output of the A/D converter 4a, respectively, in cooperation with a RAM 4d as processing memory area, according to a program stored in a ROM 4c, and realizes the functions of the frame partition means 1b, voiced/voiceless judging means 1c, aliasing signal generating means 1d, and low pass filter 1e, in FIG. 1.

The operation of the device for audio frequency range expansion or method for audio frequency range expansion shown in FIG. 2 is explained by referring to FIG. 3 and FIG. 4. At the analog-to-digital converting step 1a, the input analog narrow frequency band audio signal sent through a telephone line is converted into a digital signal by sampling at sampling frequency 2fs of four times of the upper limit frequency fs/2. For example, in the telephone line, if it is about four times of upper limit frequency of the band, the sampling frequency 2fs is 16 kHz.

FIG. 4a is a conceptual diagram showing an example of sampling row of audio signals.

FIG. 4b is a conceptual diagram showing a state of replacing sampled value 5b and 5c with a zero value pulse in every other sample of audio signal as shown by sample points 6b and 6c, respectively.

Frame partition step 1b partitions the narrow frequency band audio signal into time frames of a specific time length in the time sequence. Actually, one time frame corresponds to tens to hundreds of milliseconds. Voiced/voiceless judging step 1c analyzes and judges the audio signal converted into digital signal at analog-to-digital converting step 1a, so as to distinguish a voiceless sound section likely not containing vowel in the audio signal from a voiced sound section likely containing vowel. For example, by using the zero-cross number of the narrow frequency band audio signal included in one time frame, the voiced/voiceless judging step 1c distinguishes whether the time frame is a voiced sound section or a voiceless sound section. In the voiced sound section, the period of zero-cross is generally long, or, the zero-cross number in one time frame is small. On the other hand, in the voiceless sound section, the occurrence interval of zero-cross is short, or, the zero-cross number in one time frame is large. That is, when the zero-cross number is large in one time frame, the sound seems more likely to be voiceless. Hence, the voiced sound section and voiceless sound section can be also distinguished by making use of this characteristic. In the voiced sound section, the zero-cross is likely to occur periodically. In the voiceless sound section, the zero-cross is not periodic. Therefore, the voiced sound section and voiceless sound section can also be distinguished by making use of this difference. The voiced/voiceless judging step 1c, based on the criterion of zero-cross number set at a certain threshold, distinguishes the voiceless sound section from voiced sound section. Zero value replacing step 1d is one of methods to realize the aliasing signal generator 1d of FIG. 1. Zero value replacing step 1d replaces the value of the every other sample point 5b and 5c spuriously with zero value shown by sample point 6b and 6c, respectively, and generating a folded digital signal spuriously having frequency components of twice, at the upper limit frequency, as high as the input frequency components of narrow frequency band audio signal and having an aliasing frequency spectrum of the input signal folded symmetrically at the frequency axis fs/2 which is the upper limit frequency of input audio signal. In other words, this process folds, at the symmetry axis of fs/2 towards the high frequency side , the original digital signal having an frequency spectrum envelope (shown by envelope of solid line in FIG. 1 and FIG. 4a) to a folded signal having the folded frequency spectrum (shown by envelope of oblique hatched lines in FIG. 1 and FIG. 4b). In this case, the resulted signal from the aliasing signal generator has both frequency spectra of original one and folded one as shown by the envelope of the solid line and the oblique hatched lines in FIG. 1 and in FIG. 4b.

Based on the result of judgment at voiced/voiceless judging step 1c, low pass filter step 1e changes over the characteristic of the low pass filter to a low cut-off frequency for the voiced sound section (in this case, cut-off frequency=4 kHz), and to a high cut-off frequency for the voiceless sound section (in this case, cut-off frequency=6 kHz), so that it limits the frequency band of the output from the zero replacing step 1d.

The low pass filter 1e is also realized by the DSP/CPU 4b, and its characteristic is changed over depending on the constant given to the DSP/CPU 4b. For example, it is changed over as follows.

For voiced sound section, Cut-off frequency=4 kHz

For voiceless sound section, Cut-off frequency=6 kHz

Incidentally, instead of dividing into such two sections as voiced section and voiceless section, the frame partition step 1b may divide input signal in such multiple sections as voiced section, voiced-like section, voiceless-like divisions, and voiceless section. In this case, the voiced/voiceless judging step 1c may vary the cut-off frequency of the low pass filter at small increments, so that the “seam” of time frames of audio signals may be more smooth. Further, when the low pass filter having a smooth attenuation characteristic conforming to a formant shape of voiced sound and voiceless sound is applied in the time frame sections of audio signals, the sound may be more natural.

Digital-to-analog converting step 1f converts the output digital signal from low pass filter step 1e into an analog signal, and issues an audio signal of wide frequency band. This wide frequency band audio signal is an audio signal spuriously expanded to a band similar to an original audio signal.

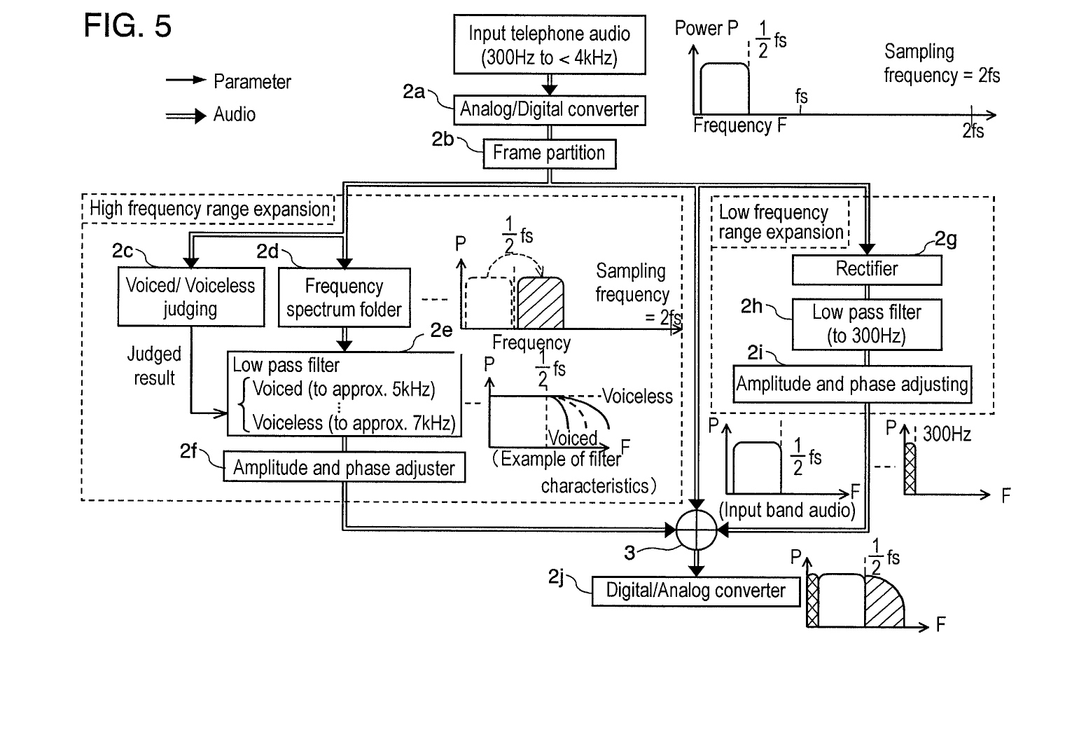

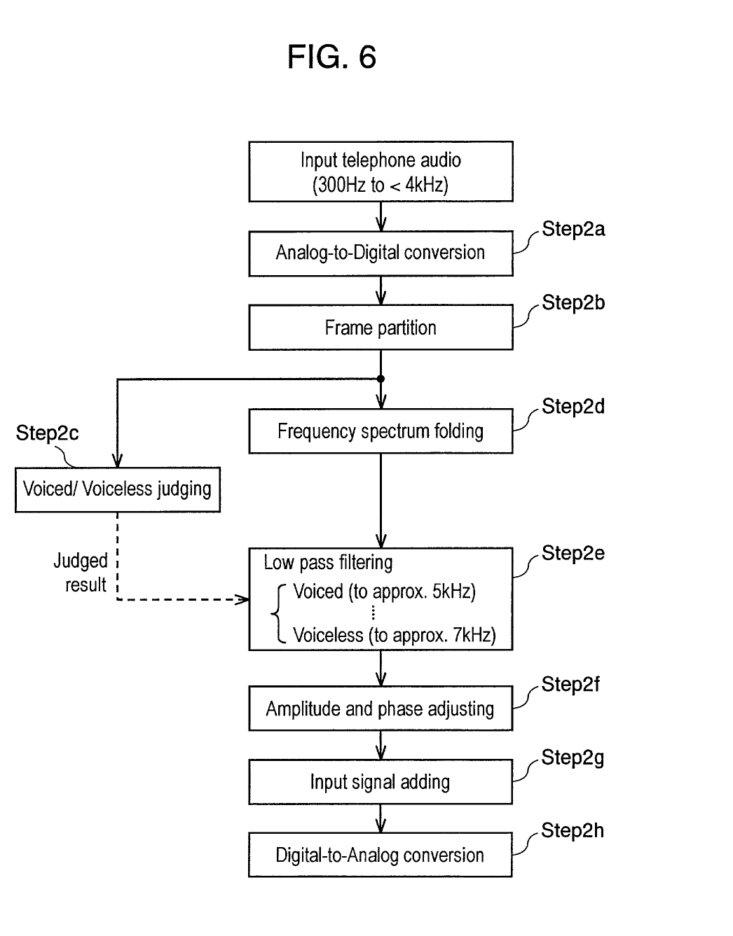

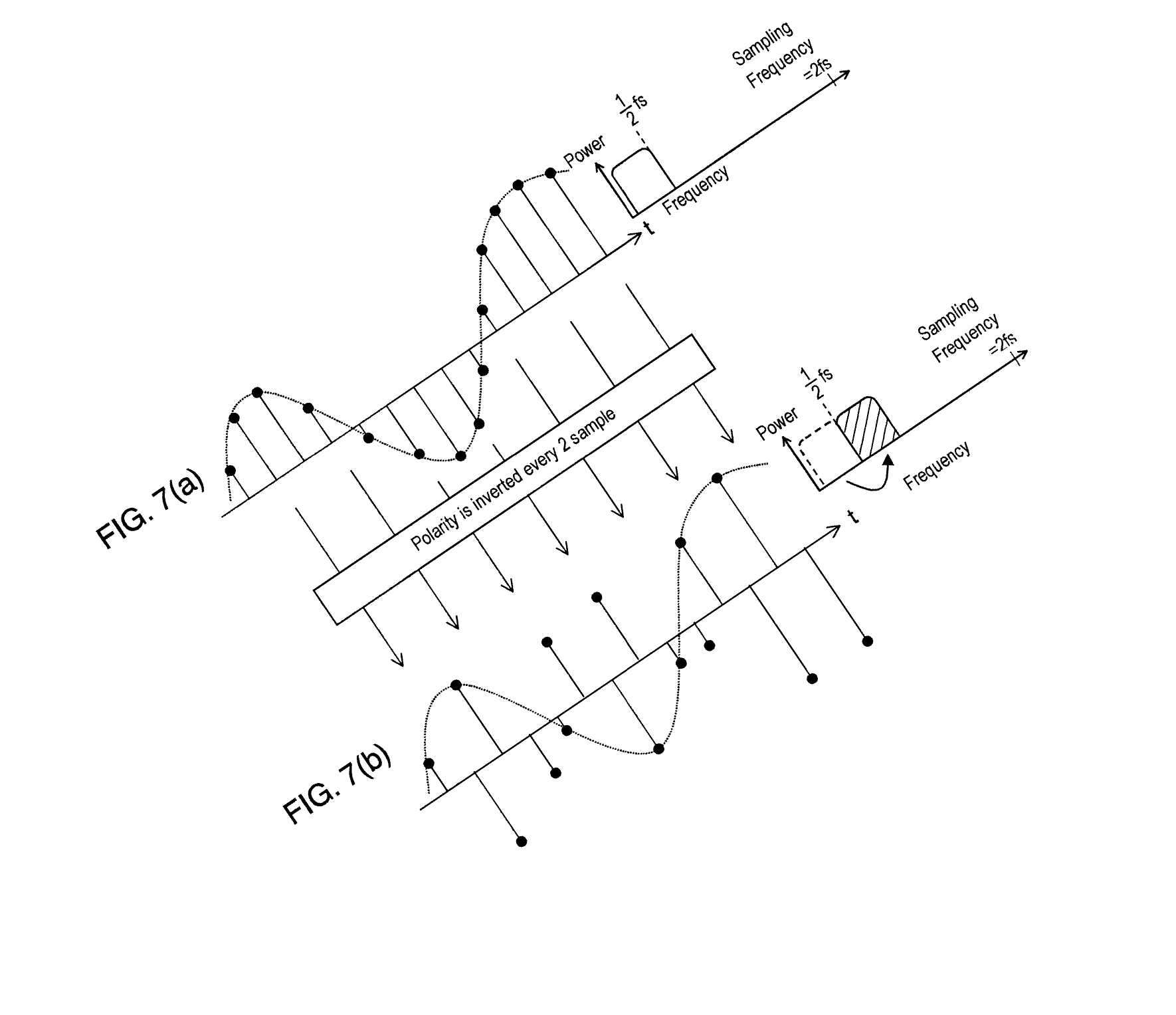

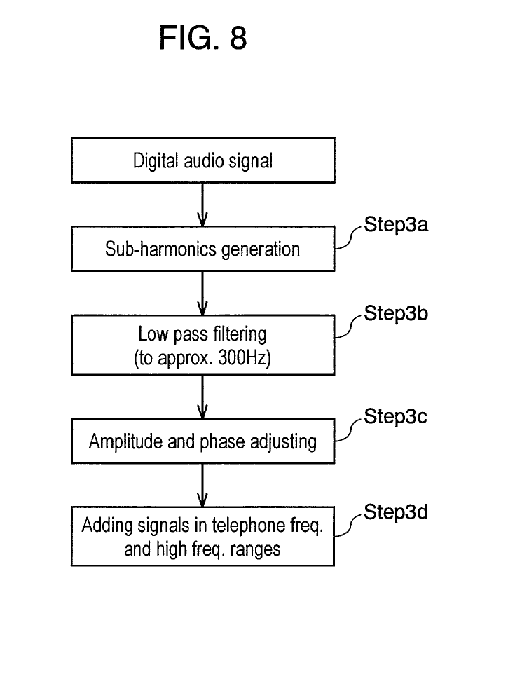

FIG. 5 is a block diagram of a device for audio frequency range expansion according to another embodiment of the invention. FIG. 6 is a flowchart of the process for audio frequency range expansion in the another embodiment in FIG. 5. FIG. 7a is a conceptual diagram showing an example of sampling of audio signals at sampling frequency 2fs. FIG. 7b is a conceptual diagram showing a state of inverting the polarity of sampling pulses in every other sample. FIG. 8 is a flowchart of the process for audio frequency range expansion according to the another embodiment in FIG. 5.

In FIG. 5, as analog-to-digital converter 2a, frame partition means 2b and voiced/voiceless judging means 2c are same as the analog-to-digital converter 1a, frame partition means 1b and voiced/voiceless judging means 1c shown in FIG. 1, respectively, and so their explanation is omitted here. Similarly, as in the section of low frequency range expansion, rectifier 2g, low pass filter 2h, amplitude and phase adjuster 2i, and digital-to-analog converter 2j are same as the rectifier 1g, low pass filter 1h, amplitude and phase adjuster 1i, and digital-to-analog converter 1j shown in the section of low frequency range expansion of FIG. 1, respectively, and so their explanation is omitted here.

In the section of high frequency range expansion in FIG. 5, a frequency spectrum folder 2d invert the polarity of sampled amplitude of every other spurious sampling point among sampling points of digital signals issued from the analog-to-digital converter 2a In this embodiment, the digital signal is converted into a double sampling frequency 2fs, and the polarity of sampled amplitude is inverted in every other sample. A low pass filter 2e limits the frequency band of the output signal of the frequency spectrum folder 2d by changing over the low pass filter characteristic to a low cut-off frequency state for the voiced sound section and a high cut-off frequency state for the voiceless sound section based on the judged result by the voiced/voiceless judging means 2c. An amplitude and phase adjuster 2f adjusts the phase and amplitude of the folded signal issued from the low pass filter 2e and having relatively high frequency.

In the section of low frequency expansion, a rectifier 2g rectifies digitally the output signal of the frame partition means 2b. Digital half wave rectifying is realized by setting the sample value to zero at every other sampling point, and issuing directly the rest of sample values as they are. Digital full wave rectifying is realized by inverting the polarity of the sample value at every other sampling point, and issuing directly the rest of sample values as they are. An adder 3 adds together at specific ratio, the output signal from the frame partition means 2b, the output signal from the amplitude and phase adjuster 2f, which is the output signal from the section of the high frequency range expansion, and the output signal of the amplitude and phase adjuster 2i, which is the output signal from the section of the low frequency range expansion.

The operation of the device for audio frequency range expansion shown in FIG. 5 is explained below by referring to the flowchart in FIG. 6, mainly about the blocks of FIG. 5 different from those of the flowchart in FIG. 3.

Analog-to-digital converting step 2a converts the input narrow frequency band audio signal into a digital signal by sampling at sampling frequency 2fs which is four times multiple of the upper limit frequency fs/2 of input signal. Frequency spectrum folding step 2d inverts the polarity of the digital sampling signal in every other sample.

FIG. 7 shows signal waveforms in the embodiment in FIG. 5 and FIG. 6. FIG. 7a shows a sequence of waveform sampled at sampling frequency 2fs, which is four times of the upper limit frequency fs/2. Inverting the polarity of the sampled pulses in FIG. 7a in every other sample, the resulted waveform is obtained as shown in FIG. 7b.

Consequently, this process folds, at the symmetry axis of fs/2 towards the high frequency side, the original digital signal having an frequency spectrum envelope (shown by envelope of broken line in FIG. 5 and FIG. 7b) to a folded signal having the folded frequency spectrum (shown by envelope of oblique hatched lines in FIG. 5 and FIG. 7b).

In this case, the resulted signal from the frequency spectrum folder has not frequency spectrum of original one shown by envelope of broken line in FIG. 5 and FIG. 7b, but has folded one as shown by the oblique hatched lines in FIG. 5 and in FIG. 7b.

The low pass filter 2e is also realized by the DSP/CPU 4b, and its characteristic is changed over depending on the constant given to the DSP/CPU 4b. In this case, for example, the cut-off frequency of low pass filter 2e is as follows.

For voiced sound section Cut-off frequency=5 kHz

For voiceless sound section Cut-off frequency=7 kHz

As mentioned above, it is changed over depending on the result from voiced/voiceless judging step 2c or frequency spectrum folding step 2d.

Amplitude and phase adjusting step 2f adjusts the amplitude and phase of the high frequency expanded signal generated at low pass filter step 2e. Herein, the effect of high frequency expansion can also be adjusted by varying the amplification factor.

Input signal adding step 2g adds together the high frequency expanded signal (shown by oblique hatched lines in FIG. 5 and in FIG. 7b) from amplitude and phase adjusting step 2f, the low frequency reinforced signal (shown by cross hatched lines in FIG. 5 and will be explained afterward), and the audio signal (shown by solid line area in FIG. 5 and in FIG. 7a) of input audio range, by using the adder 3 shown in FIG. 5. As a result, this process results in an audio signal spuriously expanded in the frequency band having a frequency spectrum as shown in the graph at the lower right corner of FIG. 5. At digital-to-analog converting step 2h converts the processed digital audio signal into an analog signal, in which the frequency band is expanded spuriously to twice as wide in frequency rage as in the original audio signal. As the result, this embodiment capable of generating an audio signal having a wide frequency band and of adjusting the degree of expansion.

The low frequency expansion process of audio signal is explained by referring to the flowchart of FIG. 8. This low frequency expansion process can be applied in any one of the foregoing embodiments.

Sub-harmonic generating step 3a processes the converted digital audio signal by half wave rectifying or full wave rectifying, and then regenerates spuriously the original fundamental frequency components of human voice from an input signal components higher than 300 HZ.

Low pass filter step 3b processes the output signal from sub-harmonic generating step 3a, and then it extracts and emphasizes the low frequency component containing the tone pitch corresponding to the fundamental frequency of the audio signal obtained by rectifying. Accordingly, this process spuriously regenerates the low frequency component of the voice lost at the time of narrowing of frequency band when passing through the telephone line. Amplitude and phase adjusting step 3c adjusts the phase and amplitude, by amplifying the low frequency signal at an arbitrary amplification factor, so that the degree of the low frequency expansion effect can be also adjusted.

Adding step 3d, similarly to the adder 3 of FIG. 5 and the input signal adding step 2g of FIG. 6, adds together the audio signal in the original frequency band (solid line area in FIG. 1 and FIG. 5), the expanded high frequency signal (oblique hatched area in FIG. 1 and FIG. 5), and the low frequency expanded portion of output signal from step 3c (cross hatched area in FIG. 1 and FIG. 5), so that an audio signal expanded both in low frequency and high frequency range is obtained, as shown the in the graph of frequency spectrum at the lower right corner of FIG. 1 or FIG. 5.

Although the embodiments of the present invention use, for convenience, the sampling frequency 2fs which is four times multiple of upper limit frequency fs/2 of input audio signal in the above-mentioned descriptions and drawings, but they can use such sampling frequency as 4fs, 6fs and so on, which are even number and more than four times multiple of upper limit frequency fs/2 of input audio signal, so as to achieve similar improvements to the embodiments described. Detail explanations of them are omitted here.

Accordingly the frequency band expanding device for audio signal of the invention can spuriously compensates the audio signal narrowed in frequency band by passing through telephone line, in the high frequency range or both high and low frequency range.

Thus, the invention can expand the frequency band of output audio signal while maintaining the feature of the voice expressed in the original audio signal frequency band width. Moreover, in the invention, the audio region of practical tone quality can be compensated by a relatively small quantity of processing operation steps. According to the invention, the present narrow frequency band audio signal of telephone or AM radio class can be substantially expanded to the wide frequency band audio signal of FM radio class or the like. The invention can also regenerates more natural audio signals by spuriously reinforcing the audio signal in low frequency band, and expanding both high frequency band and low frequency band of audio signal. Further, in the invention, the audio frequency band can be further expanded at higher tone quality by making be adjustable the level of the high frequency and low frequency signal so as to generate reinforced audio signal like the original one.

The improvement effect of the invention was evaluated by hearing test for 12 Japanese people aged from 70 to 81 years, and the following results were obtained.

The perception rate of single syllable voice has proved to be improved by 14% from 65% without any process to 79% with the invention. The tone quality evaluation in 5-point scoring system has proved to be improved by 0.5 point from 3.0 without any process to 3.5 with the invention.

In English and other languages having more consonants and voiceless sounds compared with the Japanese language, the single syllable comprehension and tone quality evaluation are expected to be improved more than in the case of the Japanese language.

Therefore, the invention is capable of solving major problems in the elderly people and others having difficulty in hearing, and can be executed in a relatively simple method and configuration, and it can be applied to various audio and acoustic appliances and in many languages around the world, and its practical merits are outstanding.

What is claimed is:

1. A device for audio frequency range expansion for generating a wide frequency band audio signal based on an input narrow frequency band audio signal comprising:
a) analog-to-digital converting means for sampling input analog narrow frequency band audio signal at a sampling frequency of substantially four times or more and even number multiple of upper limit frequency, and converting the signal into a digital signal,
b) voiced/voiceless judging means for analyzing the digital signal issued from said analog-to-digital converting means, and distinguishing a voiceless sound section not including vowel from a voiced sound section including a vowel, in the audio signal,
c) aliasing signal generating means for disposing sampled signals on every relevant order of sample point of digital signals issued from said analog-to-digital converting means, replacing the value of the every relevant order of sample point spuriously with zero value, and generating a digital signal spuriously having frequency components of twice as high as the input frequency components of narrow frequency band audio signal and having a frequency spectrum folded the spectrum of the input signal symmetrically at the frequency axis which is the upper limit frequency of input audio signal,
d) a filter for limiting the band of the output signal of said aliasing signal generating means by changing over the low pass filter characteristic to a low cut-off frequency state for the voiced sound section and a high cut-off frequency state for the voiceless sound section, based on the judged result by said voiced/voiceless judging means, and
e) signal converting means for converting a digital signal issued from said filter into an analog signal, and issuing an audio signal of wide frequency band.

2. The device for audio frequency range expansion of claim 1, further comprising:
a low frequency expander for spuriously restoring the low frequency signal lost by narrowing of frequency band of audio signal,
wherein the spuriously restored low frequency signal is added to the digital signal issued from the analog-to-digital converting means and the digital signal issued from the filter, and both high frequency band and low frequency band are expanded.

3. The device for audio frequency range expansion of claim 2,
wherein the digital signal issued from the analog-to-digital converting means is rectified, the low frequency component corresponding to the tone pitch obtained by this process is extracted by the low pass filter, and the phase and amplitude of the low frequency component are adjusted to restore the low frequency signal spuriously.

4. A device for audio frequency range expansion for generating a wide frequency band audio signal based on an input narrow frequency band audio signal comprising:
a) analog-to-digital converting means for sampling input narrow frequency band audio signal at a sampling frequency of substantially four times or more and even number multiple of upper limit frequency, and converting the signal into a digital signal,
b) voiced/voiceless judging means for analyzing the digital signal issued from said analog-to-digital converting means, and distinguishing a voiceless sound section not including vowel from a voiced sound section including a vowel, in the audio signal,
c) frequency spectrum folding means for folding frequency spectra, at the symmetry axis of the upper limit frequency of input signal towards the high frequency side, by inverting the polarity of sampled signals on every relevant order of sample point of digital signals issued from said analog-to-digital converting means,
d) a filter for limiting the band of the output signal of said band inverting means by changing over the low pass filter characteristic to a low cutoff frequency state for the voiced sound section and a high cut-off frequency state for the voiceless sound section based on the judged result by said voiced/voiceless judging means,
e) a digital adder for adding the output signal of said filter and the converted digital input signal at a specific ratio, and
f) digital-to-analog converting means for converting a digital signal issued from said digital adder into an analog signal, and obtaining an audio signal of wide frequency band.

5. The device for audio frequency range expansion of claim 4, further comprising:
a low frequency expander for spuriously restoring the low frequency signal lost by narrowing of frequency band of audio signal,
wherein the spuriously restored low frequency signal is added to the digital signal issued from the analog-to-digital converting means and the digital signal issued from the filter, and both high frequency band and low frequency band are expanded.

6. The device for audio frequency range expansion of claim 5, wherein the low frequency signal is restored spuriously by rectifying the digital signal issued from the analog-to-digital converting means, extracting low frequency component corresponding to the tone pitch obtained by this process by another low pass filter, and adjusting the phase and amplitude of the low frequency component.

7. A method for audio frequency range expansion for generating a wide frequency band audio signal based on an input narrow frequency band audio signal comprising the steps of:
a) sampling input narrow frequency band audio signal at a sampling frequency of substantially four times or more and even number multiple of upper limit frequency, and converting into digital signal,
b) judging voiced/voiceless of the digital signal for analyzing and distinguishing a voiceless sound section not including vowel from a voiced sound section including a vowel, in the audio signal,
c) aliasing by disposing sampled signals on every relevant order of sample point of digital signals issued from said analog-to-digital converting means, replacing the value of the every relevant order of sample point spuriously with zero value, and generating a digital signal including an aliasing signal spuriously having frequency components of twice as high as the input frequency components of narrow frequency band audio signal and having a frequency spectrum folded the spectrum of the input signal symmetrically at the frequency axis which is the upper limit frequency of input audio signal,
d) limiting the band of the digital signal including the aliasing signal by changing over the low pass filter characteristic to a low cut-off frequency state for the voiced sound section and a high cut-off frequency state for the voiceless sound section based on the judged result by said voiced/voiceless judging step, and
e) converting the digital signal limited in frequency band into an analog signal, and issuing an audio signal.

8. The method for audio frequency range expansion of claim 7, further comprising a step of:
spuriously restoring the low frequency signal lost by narrowing of frequency band of audio signal,
wherein the spuriously restored low frequency signal is added to the digital signal issued from the analog-to-digital converting means and the digital signal issued from the filter, and both high frequency band and low frequency band are expanded.

9. The method for audio frequency range expansion of claim 8,
wherein the digital signal converted to digital is rectified, the low frequency component corresponding to the tone pitch obtained by this process is extracted by the low pass filter, and the phase and amplitude of the low frequency component are adjusted to restore the low frequency signal spuriously.

10. A method for audio frequency range expansion for generating a wide frequency band audio signal based on an input narrow frequency band audio signal comprising the steps of:
a) sampling input analog narrow frequency band audio signal at a sampling frequency of substantially four times or even number multiple of upper limit frequency, and converting into digital signal,
b) judging voiced/voiceless of the digital signal issued from the sampling step for for analyzing and distinguishing a voiceless sound section not including vowel from a voiced sound section including a vowel, in the audio signal,
c) folding frequency spectra, at the symmetry axis of the upper limit frequency of input signal towards the high frequency side, by inverting the polarity of sampled signals on every relevant order of sample point of the digital signals issued from said analog-to-digital converting step,
d) limiting the frequency band of the digital signal inverted in the polarity at every relevant order of sample, by changing over the low pass filter characteristic to a low cut-off frequency state for the voiced sound section of input narrow frequency band audio signal and a high cut-off frequency state for the voiceless sound section based on the judged result by said voiced/voiceless judging step
e) adding the digital signal limited in the frequency band and the converted digital input signal at a specific ratio,
f) converting a digital signal issued from said adding step into an analog signal, and obtaining an audio signal of wide frequency band.

11. The method for audio frequency range expansion of claim 10, further comprising a step of:
spuriously restoring the low frequency signal lost by narrowing of frequency band of audio signal,
wherein the spuriously restored low frequency signal is added to the digital signal issued from the analog-to-digital converting step and the digital signal issued from the limiting step, and both high frequency band and low frequency band are expanded.

12. The method for audio frequency range expansion of claim 11,
wherein the low frequency signal is restored spuriously by rectifying the digital signal issued from the analog-to-digital converting step, extracting low frequency component corresponding to the tone pitch obtained by this process by another low pass filtering step, and adjusting the phase and amplitude of the low frequency component.
